(19) United States
(12) Patent Application Publication
(10) Pub. No.: US 2025/0158494 A1
(43) Pub. Date: May 15, 2025

(54) ELECTRIC-MOTOR DRIVE CONTROL DEVICE

(71) Applicant: HITACHI ASTEMO, LTD., Hitachinaka-shi, Ibaraki (JP)

(72) Inventors: Kazuhiko NAKANO, Hitachinaka-shi, Ibaraki (JP); Kyosuke HASEGAWA, Hitachinaka-shi, Ibaraki (JP)

(73) Assignee: HITACHI ASTEMO, LTD., Hitachinaka-shi, Ibaraki (JP)

(21) Appl. No.: 18/838,715

(22) PCT Filed: Jan. 26, 2023
(86) PCT No.: PCT/JP2023/002368

§ 371 Date: Aug. 15, 2024

(30) Foreign Application Priority Data
Apr. 13, 2022 (JP) 2022-066215

(51) Int. Cl. H02K 11/33; H01R 4/02; H05K 3/34

(52) U.S. Cl. CPC H02K 11/33; H01R 4/028; H05K 3/3489; H05K 2203/0736

(57) ABSTRACT

An electric-motor drive control device can suppress dripping of flux applied in a pre-soldering process when a printed circuit board is mounted on the back surface of a connector block. The electric-motor drive control device includes a connector block including a connection port in which a terminal is partially exposed and the exposed terminal is connected to a terminal of a counterpart connector, and an exterior part that is joined to the connector block and houses and seals a printed circuit board used for drive control of an electric motor. The connector block includes a soldered terminal that is the terminal protruding from the back surface of the connector block, the back surface facing a space in which the printed circuit board is housed, and a reservoir that is provided on the back surface and retains excess flux applied to and flowing away from the soldered terminal.

### TECHNICAL FIELD

The present invention relates to an electric-motor drive control device and, more particularly, relates to a technology for suppressing the dripping of flux that is applied in a pre-soldering process when a printed circuit board is mounted on the back surface of a connector block.

### BACKGROUND ART

Patent Document 1 describes a spray-type flux application device for spraying flux onto the surface of a printed circuit board before soldering electronic components to the printed circuit board. In Patent Document 1, a spray controller is provided to control the range within which a flux liquid sprayed from a spray nozzle is dispersed, thereby properly controlling the spray area of the flux liquid.

### REFERENCE DOCUMENT LIST

### Patent Document

Patent Document 1: JP 2003-347719 A

### SUMMARY OF THE INVENTION

### Problem to be Solved by the Invention

It is known that although flux improves the wettability of solder, flux residue may cause migration and inhibit the hardening of a formed-in-place gasket (FIPG). When a flux liquid is sprayed, as in Patent Document 1, the flux liquid may flow to the side surface of a connector block via a through hole of a printed circuit board due to, for example, unevenness of the sprayed flux liquid.

Excess flux flowed to the side surface of the connector block is highly likely to adhere to a seal of an exterior part or adhere to a glove of a worker who may then unintentionally cause flux to adhere (or be transferred) to the seal. This makes it necessary to visually inspect flux residue that has dripped to the side surface of the connector block and manually wipe off this flux residue. This in turn complicates a mounting process and increases manufacturing costs related to flux.

The present invention is made in view of the above problem. An object of the present invention is to provide a drive control device for an electric motor so as to suppress the dripping of flux that is applied in a pre-soldering process when a printed circuit board is mounted on a connector block, thereby reducing manufacturing costs related to flux.

### Means for Solving the Problem

An aspect of the present invention provides a drive control device for an electric motor that has a connector block including a connection port in which a terminal is partially exposed and the exposed terminal is connected to a terminal of a counterpart connector, and an exterior part that is joined to the connector block and houses and seals a printed circuit board used for drive control of an electric motor. The connector block includes a soldered terminal that is the terminal protruding from the back surface of the connector block, the back surface facing a space in which the printed circuit board is housed, and a reservoir that is provided on the back surface and retains excess flux applied to and subsequently flowing away from the soldered terminal.

### Effects of the Invention

According to the present invention, a reservoir for excess flux is provided. When mounting a printed circuit board on a connector block, this configuration makes it possible to retain excess flux applied in a pre-soldering process in the reservoir and thereby makes it possible to prevent the excess flux from dripping to the side surface of the connector block. This in turn makes it possible to prevent excess flux from adhering to a seal of an exterior part or from being transferred from a glove to the seal, and thereby makes it possible to stably produce high-quality products. This configuration also makes it possible to reduce manufacturing cost by reducing work such as visually inspecting flux residue and manually wiping off flux residue.

### BRIEF DESCRIPTION OF THE DRAWINGS

FIG. 1 is a plan view of the back surface of a connector block of an electric-motor drive control device according to an embodiment of the present invention.

FIG. 2 is a perspective view of the connector block illustrated in FIG. 1.

FIG. 3 is a perspective view for describing a process of mounting a printed circuit board on the back surface of the connector block illustrated in FIG. 2.

FIG. 4 is an external perspective view of the electric-motor drive control device according to the embodiment of the present invention.

FIG. 5 is an exploded perspective view of the electric-motor drive control device illustrated in FIG. 4.

FIG. 6 is a front view for describing a flux application process.

FIG. 7 is a front view for describing another example of a flux application process.

FIG. 8 is an enlarged cross-sectional view for describing the flow of a flux liquid on a soldered terminal in the flux application process illustrated in FIG. 6.

FIG. 9A is a cross-sectional view illustrating a first variation of a reservoir for excess flux.

FIG. 9B is a cross-sectional view illustrating a second variation of a reservoir for excess flux.

FIG. 9C is a cross-sectional view illustrating a third variation of a reservoir for excess flux.

FIG. 9D is a cross-sectional view illustrating a fourth variation of a reservoir for excess flux.

FIG. 9E is a cross-sectional view illustrating a fifth variation of a reservoir for excess flux.

FIG. 9F is a cross-sectional view illustrating a sixth variation of a reservoir for excess flux.

FIG. 9G is a cross-sectional view illustrating a seventh variation of a reservoir for excess flux.

FIG. 9H is a cross-sectional view illustrating an eighth variation of a reservoir for excess flux.

FIG. 9I is a cross-sectional view illustrating a ninth variation of a reservoir for excess flux.

### MODE FOR CARRYING OUT THE INVENTION

An embodiment of the present invention is described below with reference to the drawings.

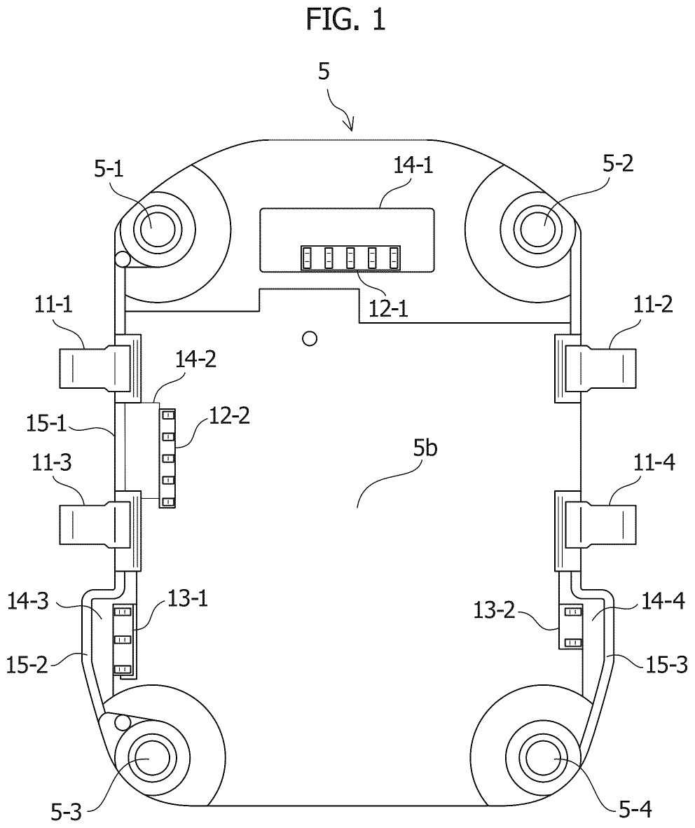

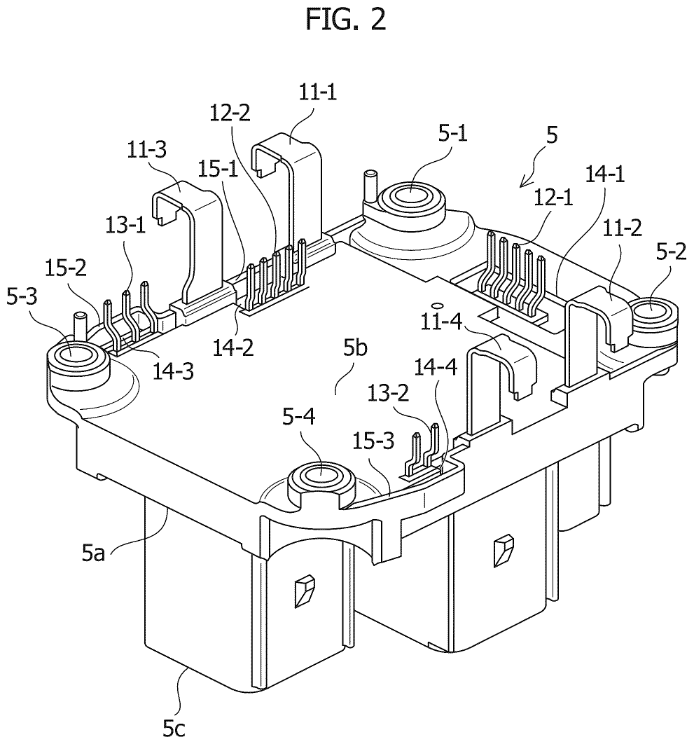

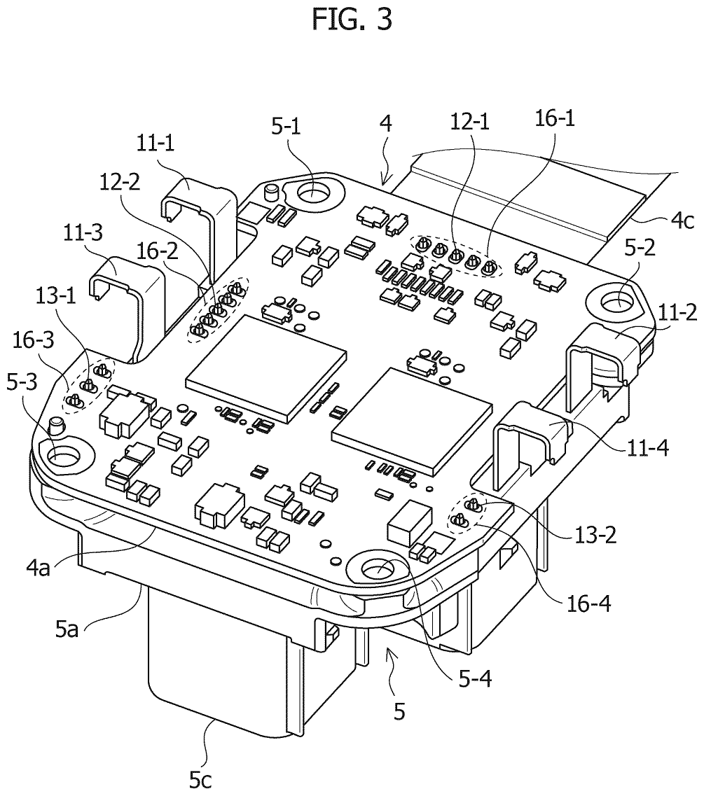

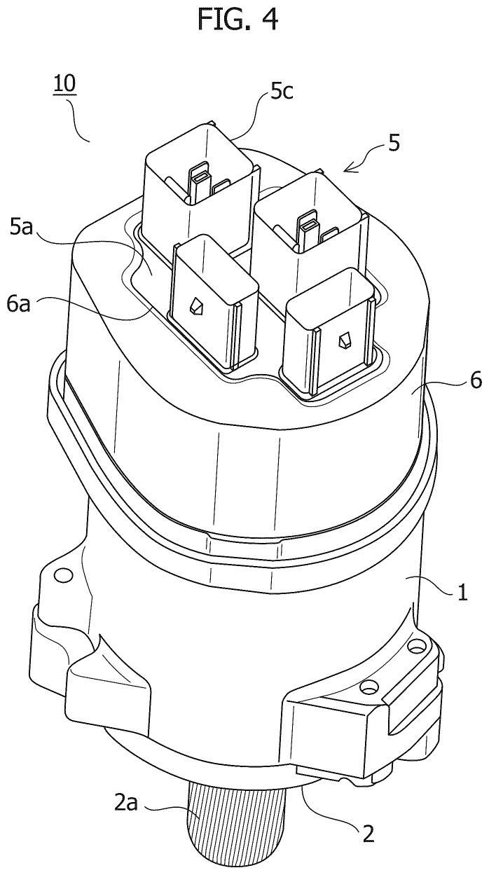

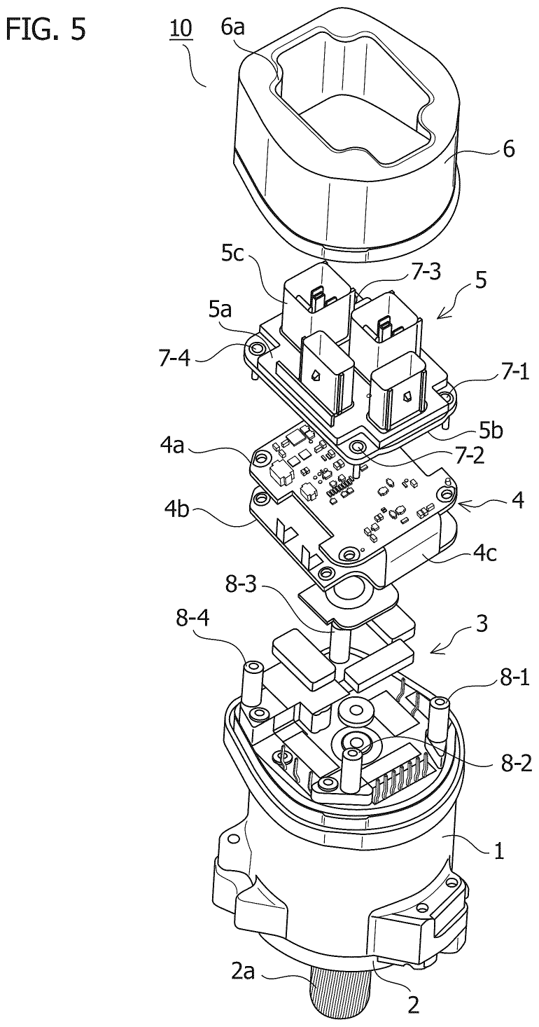

FIGS. 1 through 5 illustrate an electric-motor drive control device according to an embodiment of the present invention. FIG. 1 is a plan view of the back surface of a connector block, FIG. 2 is a perspective view of the connector block seen from the back side, and FIG. 3 is a perspective view for describing a process of mounting a printed circuit board on the back surface of the connector block. FIG. 4 is an external perspective view of the electric-motor drive control device, and FIG. 5 is an exploded perspective view of the electric-motor drive control device illustrated in FIG. 4.

For example, the electric-motor drive control device is applied to an electric steering device of a vehicle and is used for drive control of an electric motor that generates or assists steering force.

As illustrated in FIGS. 4 and 5, an electric-motor drive control device 10 includes a motor body 2 housed in an exterior part (cover) 1, a mounted component 3 that controls the driving of motor body 2, a printed circuit board (PCB) 4 on which various electronic components are mounted, and a connector block 5. Mounted component 3, printed circuit board 4, and connector block 5 are attached to motor body 2 and covered by an exterior part (cover) 6.

Exterior parts 1 and 6 form a pair and are joined together via a sealing material (not shown). A motor shaft and a gear 2a attached to the motor shaft protrude from one side of exterior part 1, an opening 6a is formed on the opposing side of exterior part 6, and a connection port 5c protrudes from a front surface 5a of connector block 5.

Connector block 5 illustrated in FIGS. 1 and 2 is a molded part in which parts of terminals are sealed. Connection port 5c, in which terminals are connected to terminals of a counterpart connector, is provided on front surface 5a of connector block 5. Collars 5-1 to 5-4, which are made thicker to increase durability, are formed at four corners of connector block 5. Screws 7-1 to 7-4 are inserted into collars 5-1 to 5-4 and then screwed into screw receiving parts 8-1 to 8-4 of cover 1 such that mounted component 3, printed circuit board 4, and connector block 5 are fixed together (see FIG. 5).

On a back surface 5b of connector block 5, sensor input terminals 12-1 and 12-2 and CAN communication terminals 13-1 and 13-2 are provided as examples of terminals. Power supply terminals 11-1 to 11-4 are connected to terminals on printed circuit board 4 by TIG welding. Also, as illustrated in FIG. 3, sensor input terminals 12-1 and 12-2 and CAN communication terminals 13-1 and 13-2 are inserted into through holes of printed circuit board 4 to form soldered terminals that are soldered to wires of printed circuit board 4.

A recess 14-1 with a rectangular opening is provided on back surface 5b of connector block 5. In recess 14-1, a row of sensor input terminals 12-1 is disposed adjacent to a long side of recess 14-1 that is away from the outer edge of back surface 5b. Recess 14-1 functions as a reservoir for retaining excess flux applied to and subsequently flowing away from sensor input terminals 12-1.

A barrier 15-1 is provided on the outer edge of back surface 5b of connector block 5 at a position corresponding to the row of sensor input terminals 12-2. A recess 14-2 is provided between barrier 15-1 and sensor input terminals 12-2 and adjacent to the row of sensor input terminals 12-2. Barrier 15-1 and recess 14-2 form a reservoir for retaining excess flux applied to and subsequently flowing away from sensor input terminals 12-2.

Similarly, barriers 15-2 and 15-3 are provided on the outer edge of back surface 5b of connector block 5 at positions corresponding to CAN communication terminals 13-1 and 13-2. A recess 14-3 is provided between CAN communication terminals 13-1 and barrier 15-2, and a recess 14-4 is provided between CAN communication terminals 13-2 and barrier 15-3.

The pair of barrier 15-2 and recess 14-3 and the pair of barrier 15-3 and recess 14-4 form reservoirs for retaining excess flux applied to and subsequently flowing away from CAN communication terminals 13-1 and 13-2.

Thus, excess flux from sensor input terminals 12-1, which are disposed far from the outer edge, is retained in recess 14-1. On the other hand, excess flux from sensor input terminals 12-2, which are disposed close to the outer edge, is retained by barrier 15-1 and recess 14-2. Also, excess flux from CAN communication terminals 13-1, which are disposed close to the outer edge, is retained by barrier 15-2 and recess 14-3; and excess flux from CAN communication terminals 13-2, which are disposed close to the outer edge, is retained by barrier 15-3 and recess 14-4.

As illustrated in FIG. 5, printed circuit board 4 has a configuration in which first and second mounting parts 4a and 4b, which correspond to the planar shape of back surface 5b of connector block 5, are connected to each other by a flexible part 4c. On the first and second mounting parts 4a and 4b, semiconductor devices, such as FETs, and various electronic components are mounted. As illustrated in FIG. 3, first mounting part 4a is placed on back surface 5b of connector block 5 such that sensor input terminals 12-1 and 12-2 and CAN communication terminals 13-1 and 13-2 are inserted into the through holes of first mounting part 4a. Areas around these terminals on the surface of the first mounting part 4a are referred to as areas 16-1, 16-2, 16-3, and 16-4 onto which a fluxing agent is sprayed. After the fluxing agent is sprayed, soldering is performed. Next, second mounting part 4b is placed on first mounting part 4a. As a result, printed circuit board 4 is mounted on back surface 5b of connector block 5.

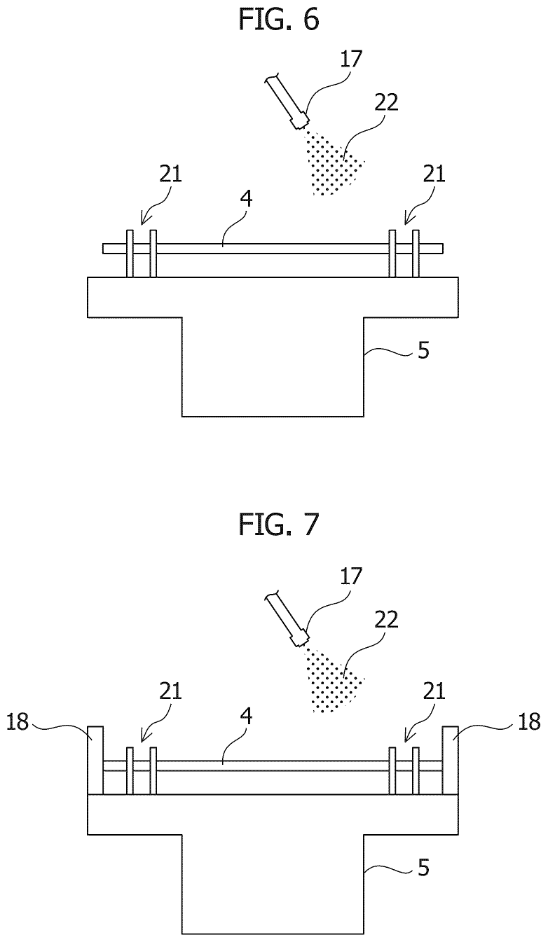

FIG. 6 illustrates a flux application process. After printed circuit board 4 is mounted on back surface 5b of connector block 5 as illustrated in FIG. 3, a fluxing agent 22 is sprayed from a spray nozzle 17 onto soldered terminals 21 (each of areas 16-1, 16-2, 16-3, and 16-4 in FIG. 3 that are enclosed by dashed lines and surround sensor input terminals 12-1 and 12-2 and CAN communication terminals 13-1 and 13-2).

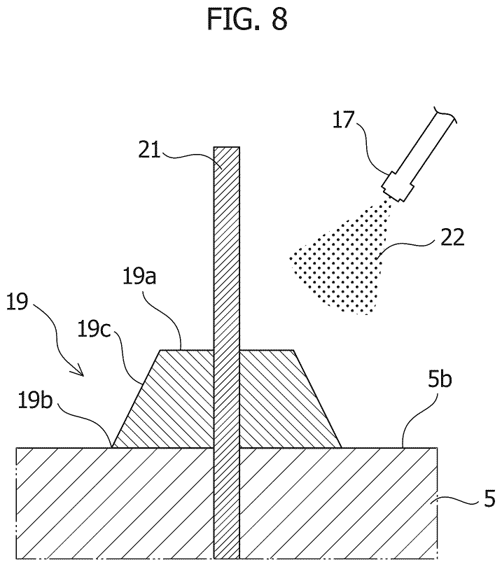

In the flux application process, as illustrated in FIG. 7, a protective wall 18 may be provided along the outer edge of back surface 5b of connector block 5. Providing protective wall 18 makes it possible to reduce scattering of fluxing agent 22 sprayed from spray nozzle 17.

When fluxing agent 22 is sprayed, excess flux flowing away from a portion (area 16-1) including sensor input terminals 12-1 is retained in the reservoir formed by recess 14-1. Also, excess flux flowing away from a portion (area 16-2) including sensor input terminals 12-2 is retained in the reservoir formed by recess 14-2 and barrier 15-1.

Similarly, excess flux flowing away from a portion (area 16-3) including CAN communication terminals 13-1 is retained in the reservoir formed by recess 14-3 and barrier 15-2. Excess flux flowing away from a portion (area 16-4) including CAN communication terminals 13-2 is retained in the reservoir formed by recess 14-3 and barrier 15-3.

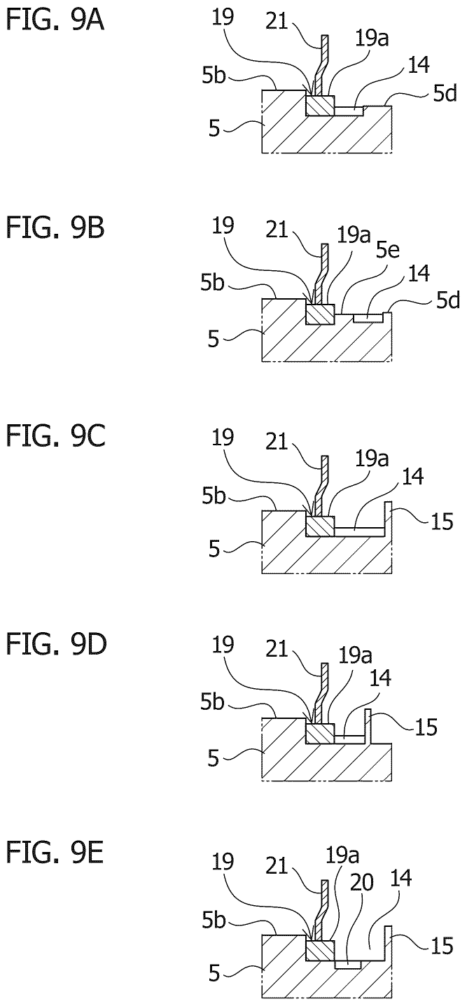

FIG. 8 is an enlarged view of soldered terminal 21 (each of sensor input terminals 12-1 and 12-2 and CAN communication terminals 13-1 and 13-2). A raised part 19 is formed at the base of soldered terminal 21. Raised part 19 is formed to protrude upward from back surface 5b of connector block 5 and has a bottom surface 19b and an upper surface 19a that is narrower than bottom surface 19b. With narrower upper surface 19a, excess flux is more smoothly guided to the recess along an inclined surface 19c, and the amount of remaining flux can be reduced.

Furthermore, raised part 19 makes it possible to prevent accumulation of flux and an increase of flux droplets at the base of soldered terminal 21 and thereby makes it possible to reduce flux that flows toward the outer edge in the form of droplets. This in turn makes it possible to reduce the risk of migration caused by flux residue entering the interface between the resin of connector block 5 and soldered terminal 21.

Also, the amount of remaining flux can be further reduced by sloping or rounding upper surface 19a of raised part 19.

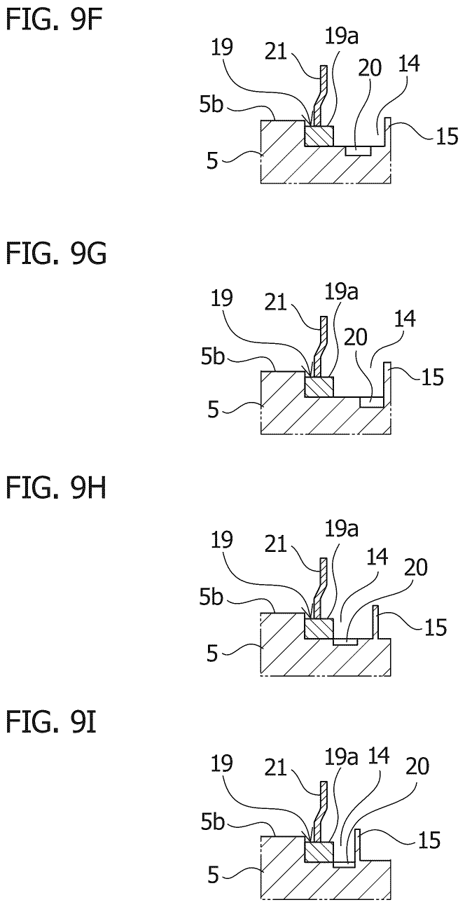

FIGS. 9A to 9I are cross-sectional views illustrating variations of reservoirs for excess flux. In these figures, the cross section of raised part 19 has a rectangular shape (that is, the bottom surface and the upper surface have the same width). However, the upper surface of raised part 19 is preferably narrower than the bottom surface as described above, and the upper surface of raised part 19 is more preferably sloped or rounded.

FIG. 9A illustrates an example in which raised part 19 is disposed in a recess 14. In this example, upper surface 19a of raised part 19 is lower than back surface 5b of connector block 5, and an upper part 5d of the outer edge of connector block 5 is lower than upper surface 19a of raised part 19. In this case, excess flux is retained in recess 14 up to upper part 5d of the outer edge of connector block 5.

FIG. 9B illustrates an example in which raised part 19 and recess 14 are disposed apart from each other. In this example, upper surface 19a of raised part 19 is lower than back surface 5b of connector block 5, and a separating part 5e, positioned at the same height as upper part 5d of the outer edge of connector block 5, is formed between raised part 19 and recess 14. Separation part 5e and upper part 5d of the outer edge are lower than upper surface 19a of raised part 19. In this case, excess flux flows over separating part 5e and is retained in recess 14 up to upper part 5d of the outer edge of connector block 5.

FIG. 9C illustrates an example in which raised part 19 is disposed in recess 14, and a barrier 15 is formed on the outer edge of connector block 5. In this example, upper surface 19a of raised part 19 is lower than back surface 5b of connector block 5, and barrier 15 is higher than upper surface 19a of raised part 19. In this case, excess flux is retained in recess 14 up to back surface 5b of connector block 5.

FIG. 9D illustrates an example in which raised part 19 is disposed in recess 14, and barrier 15 is formed at a position closer to the center of connector block 5 than the outer edge of connector block 5. FIG. 9D differs from FIG. 9C only in the position of barrier 15, and other components of FIG. 9D are the same as those of FIG. 9C. Therefore, the same reference numbers are assigned to these components, and detailed descriptions thereof are omitted.

Each of FIGS. 9E, 9F, and 9G illustrates an example in which a groove 20 is also formed in recess 14 illustrated in FIG. 9C. In FIG. 9E, one end of groove 20 is adjacent to the base of raised part 19; and in FIG. 9F, groove 20 is formed at an intermediate position between raised part 19 and barrier 15. In FIG. 9G, one end of groove 20 is adjacent to the base of barrier 15. Thus, FIGS. 9E, 9F, and 9G differ from each other only in the position of groove 20, and other components of FIGS. 9E, 9F, and 9G are the same. Therefore the same reference numbers are assigned to these components, and detailed descriptions thereof are omitted.

Each of FIGS. 9H and 9I illustrates an example in which the position of barrier 15 in the configuration of FIG. 9E is shifted. In FIG. 9H, barrier 15 is formed between groove 20 and the outer edge of connector block 5, and in FIG. 9I, barrier 15 is disposed adjacent to one end of groove 20. Thus, FIGS. 9H and 9I are different from FIG. 9E only in the position of barrier 15, and other components of FIGS. 9H and 9I are the same as those of FIG. 9E. Therefore, the same reference numbers are assigned to these components, and detailed descriptions thereof are omitted.

As described above, the reservoir may be modified in various manners and be used to retain excess flux.

As described above, according to the present invention, a reservoir for excess flux is provided. When mounting a printed circuit board on the back surface of a connector block, this configuration makes it possible to retain an excess of a fluxing agent applied in a pre-soldering process in the reservoir and thereby makes it possible to prevent excess fluxing agent from dripping to the side surface of the connector block.

This in turn makes it possible to prevent the occurrence of migration and the inhibition of hardening of a seal caused by flux residue, and makes it possible to stably supply high-quality products. Also, the above configuration makes it possible to reduce manufacturing cost by reducing work such as visually inspecting flux residue and manually wiping off flux residue.

The configurations and control methods in the above embodiment are only schematically described to an extent that the present invention can be understood and implemented. Accordingly, the present invention is not limited to the above-described embodiment and can be modified in various manners within the scope of the technical concepts represented by the claims.

### REFERENCE SYMBOL LIST

1 . . . exterior part (cover), 2 . . . motor body, 3 . . . mounted component, 4 . . . printed circuit board, 5 . . . connector block, 5-1 to 5-4 . . . collar, 5a . . . front surface, 5b . . . back surface, 5c . . . connection port, 6 . . . exterior part (cover), 6a . . . opening, 7-1 to 7-4 . . . screw, 8-1 to 8-4 . . . screw receiving part, 10 . . . electric-motor drive control device, 11-1 to 11-4 . . . power supply terminal, 12-1, 12-2 . . . sensor input terminal (soldered terminal), 13-1, 13-2 . . . . CAN communication terminal (soldered terminal), 14-1 to 14-4, 14 . . . recess (reservoir), 15-1 to 15-3, 15 . . . barrier (reservoir), 16-1 to 16-4 . . . area, 17 . . . spray nozzle, 18 . . . protective wall, 19 . . . raised part, 20 . . . groove, 21 . . . soldered terminal, 22 . . . fluxing agent

1. An electric-motor drive control device comprising:
a connector block including a connection port in which a terminal is partially exposed and the exposed terminal is connected to a terminal of a counterpart connector; and
an exterior part that is joined to the connector block and houses and seals a printed circuit board used for drive control of an electric motor, wherein
the connector block includes:
a soldered terminal that is the terminal protruding from a back surface of the connector block, the back surface facing a space in which the printed circuit board is housed, and
a reservoir that is provided on the back surface and retains excess flux applied to and subsequently flowing away from the soldered terminal.

2. The electric-motor drive control device according to claim 1, wherein
the soldered terminal is formed in a position overlapping the printed circuit board.

3. The electric-motor drive control device according to claim 1, wherein
the reservoir is a recess that is lower than an outer edge of the back surface from which the soldered terminal protrudes.

4. The electric-motor drive control device according to claim 1, wherein
the reservoir includes a recess that is lower than an outer edge of the back surface from which the soldered terminal protrudes and a barrier that is erected on the back surface at a position closer to the outer edge than the soldered terminal.

5. An electric-motor drive control device comprising:
a connector block including a connection port in which a terminal is partially exposed and the exposed terminal is connected to a terminal of a counterpart connector; and
an exterior part that is joined to the connector block and houses and seals a printed circuit board used for drive control of an electric motor, wherein
the connector block includes:
a soldered terminal that is the terminal protruding from a back surface of the connector block, the back surface facing a space in which the printed circuit board is housed, and
a recess that is lower than an outer edge of the back surface and is formed on an outer side of the back surface relative to the soldered terminal.

6. The electric-motor drive control device according to claim 5, further comprising:
a raised part formed at a base of the soldered terminal.

7. The electric-motor drive control device according to claim 6, wherein
an inclined part of the raised part is connected to the recess.

8. The electric-motor drive control device according to claim 5, wherein
the soldered terminal is disposed in the recess.

9. The electric-motor drive control device according to claim 5, wherein
the recess is disposed in a direction of the outer edge of the connector block that is at a shortest distance from the soldered terminal.

10. The electric-motor drive control device according to claim 5, wherein
the recess is separated from the soldered terminal and is disposed between the soldered terminal and the outer edge of the connector block.

11. The electric-motor drive control device according to claim 5, wherein
the recess extends between an attachment position of the connector block and the soldered terminal.

12. An electric-motor drive control device comprising:
a connector block including a connection port in which a terminal is partially exposed and the exposed terminal is connected to a terminal of a counterpart connector; and
an exterior part that is joined to the connector block and houses and seals a printed circuit board used for drive control of an electric motor, wherein
the connector block includes:
a soldered terminal that is the terminal protruding from a back surface of the connector block, the back surface facing a space in which the printed circuit board is housed, and
a barrier that is disposed on an outer side of the back surface relative to the soldered terminal and protrudes from the back surface.

13. The electric-motor drive control device according to claim 12, wherein
the barrier extends between an attachment position of the connector block and the soldered terminal.

14. The electric-motor drive control device according to claim 13, further comprising:
a recess that is lower than an outer edge of the back surface and disposed between the barrier and the soldered terminal.
